(19) United States
(12) Patent Application Publication
(10) Pub. No.: US 2026/0271655 A1
(43) Pub. Date: Sep. 10, 2026

(54) THERMAL PROCESSING APPARATUS

(71) Applicant: ProAsia Semiconductor Corporation, Hsinchu City (TW)

(72) Inventors: Tun-Yuan Cheng, Hsinchu City (TW); Kang-Cheng Lai, Hsinchu City (TW)

(21) Appl. No.: 19/408,996

(22) Filed: Dec. 4, 2025

(30) Foreign Application Priority Data
Mar. 4, 2025 (TW) 114107961

(51) Int. Cl. H01L 21/67; H01L 21/687

(52) U.S. Cl. CPC H10P 72/0436; H10P 72/7616

(57) ABSTRACT

The present invention relates to a thermal processing apparatus. The thermal processing apparatus comprises a processing chamber, a rotating susceptor, a plurality of airflow-driving elements, a support element, and a heat source. The processing chamber has an inlet and an outlet. The rotating susceptor is disposed within the processing chamber and includes a bearing that allows the rotating susceptor to rotate relative to the processing chamber. The plurality of airflow-driving elements are spaced apart and arranged around an outer surface of the rotating susceptor. The support element is disposed on the rotating susceptor and is configured to carry a substrate. The heat source is arranged on a surface of the processing chamber to provide radiant heat energy to the substrate on the support element. When a gas enters the processing chamber through the inlet, it drives the airflow-driving elements, causing the rotating susceptor to rotate along with the support element, and is subsequently discharged through the outlet.

### CROSS-REFERENCES TO RELATED APPLICATIONS

This application claims the benefit of priority to Taiwanese Patent Application No. 114107961 filed on Mar. 4, 2025, which is hereby incorporated by reference in its entirety.

### BACKGROUND OF THE INVENTION

### Field of the Invention

The present invention relates to a thermal processing apparatus. More specifically, the present invention relates to a thermal processing apparatus for uniformly heating a semiconductor substrate during a thermal processing procedure.

### Descriptions of the Related Art

Rapid Thermal Processing (RTP) is a widely used thermal processing technique in semiconductor manufacturing, primarily applied for surface modification of thin films, dopant activation, and stress relief. By using a high-power thermal radiation source, such as heating lamps, to achieve rapid heating and cooling, the electrical and physical properties of the substrate can be altered under controlled temperature conditions—for example, reducing resistance, changing the dielectric constant, or improving film uniformity— making rapid thermal processing an essential technology in modern semiconductor fabrication.

Although rapid thermal processing offers the advantage of fast heating and cooling, providing a stable temperature to uniformly heat all regions of the substrate remains a persistent challenge. Temperature variations may arise due to uneven radiation intensity from the heating lamps, differences in the materials on the substrate surface, or the thermal conductivity of the substrate support, which can lead to inconsistent process results. To improve heating uniformity, the industry has attempted to rotate the substrate to evenly distribute the thermal radiation. However, the internal chamber of rapid thermal processing equipment must maintain an oxygen-free environment, typically filled only with nitrogen, and the internal rotating components must meet reliability requirements, avoid particle generation, and withstand high temperatures, which increases both the cost and complexity of the equipment.

Therefore, providing uniform temperature control for the substrate while maintaining process stability and reliability in a cost-effective thermal processing apparatus has become a critical issue that needs to be addressed in current thermal processing technology.

### SUMMARY OF THE INVENTION

The objective of the present invention is to provide, during the thermal processing in semiconductor manufacturing, a mechanism in which a rotating susceptor is driven by airflow so that the wafers inside the thermal processing apparatus are heated while rotating, thereby creating a uniformly heated processing environment.

To achieve the above objective, the present invention discloses a thermal processing apparatus, comprising a processing chamber, a rotating susceptor, a plurality of airflow-driving elements, a support element, and a heat source. The processing chamber has an inlet and an outlet. The rotating susceptor is disposed within the processing chamber and includes a bearing that allows the rotating susceptor to rotate relative to the processing chamber. The airflow-driving elements are spaced apart and arranged around an outer surface of the rotating susceptor. The support element is disposed on the rotating susceptor and is configured to carry a substrate. The heat source is arranged on a surface of the processing chamber to provide radiant heat energy to the substrate on the support element. When a gas enters the processing chamber through the inlet, the gas drives the airflow-driving elements to causing the rotating susceptor to rotate along with the support element, and is subsequently discharged through the outlet.

In one embodiment of the present invention, a bottom surface of the rotating susceptor has a first annular groove, and the bearing comprises a plurality of balls that are partially accommodated in the first annular groove.

In one embodiment of the present invention, an inner bottom surface of the processing chamber has a second annular groove, and the balls are partially accommodated in the second annular groove.

In one embodiment of the present invention, the airflow-driving elements comprise a plurality of blades.

In one embodiment of the present invention, the number of the airflow-driving elements is from 4 to 16.

In one embodiment of the present invention, each of the airflow-driving elements has a windward surface, a length of the windward surface is 20 millimeters (mm), and a width of the windward surface is 10 millimeters (mm).

In one embodiment of the present invention, each of the airflow-driving elements forms an angle of 15 to 90 degrees with an upper surface of the rotating susceptor.

In one embodiment of the present invention, the bearing is disposed on a lower surface of the rotating susceptor and is selected from a ball bearing, a needle bearing, a tapered roller bearing, a sleeve bearing, a magnetic bearing, an air bearing, or a fluid bearing.

In one embodiment of the present invention, the support element is made of graphite.

In one embodiment of the present invention, an outer surface of the support element has a silicon carbide (SiC) coating.

In one embodiment of the present invention, the rotating susceptor is made of quartz.

In one embodiment of the present invention, the inlet and the outlet are disposed on two opposing sides of the processing chamber, and the inlet is arranged on a side wall of the processing chamber.

In one embodiment of the present invention, an inflow direction of the inlet forms an oblique angle with an installation plane of the processing chamber, and the oblique angle is less than 90 degrees.

In one embodiment of the present invention, a flow rate of the gas is 20 to 120 liters per minute.

In one embodiment of the present invention, the gas is nitrogen.

In one embodiment of the present invention, a gas pressure of the gas is 1 atmosphere (atm).

In one embodiment of the present invention, the heat source comprises a plurality of upper heating elements and a plurality of lower heating elements, which are respectively disposed on an upper surface and a lower surface of the processing chamber.

After referring to the drawings and the embodiments as described in the following, those having ordinary skill in the art can understand other objectives of the present invention, as well as the technical means and embodiments of the present invention.

### BRIEF DESCRIPTION OF THE DRAWINGS

FIG. 1 is a side cross-sectional view of a thermal processing apparatus according to an embodiment of the present invention;

FIG. 2 is a top view of the rotating susceptor and the airflow-driving elements of the thermal processing apparatus according to an embodiment of the present invention; and

FIG. 3 is a bottom view of the rotating susceptor and the airflow-driving elements of the thermal processing apparatus according to an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application, or particular method for implementations described in these embodiments. Therefore, the description of these embodiments is for illustrative purposes only and is not intended to limit the present invention. In the following embodiments and drawings, components not directly related to the present invention are omitted, and the dimensional relationships among the elements in the drawings are shown for ease of understanding and are not intended to limit actual proportions.

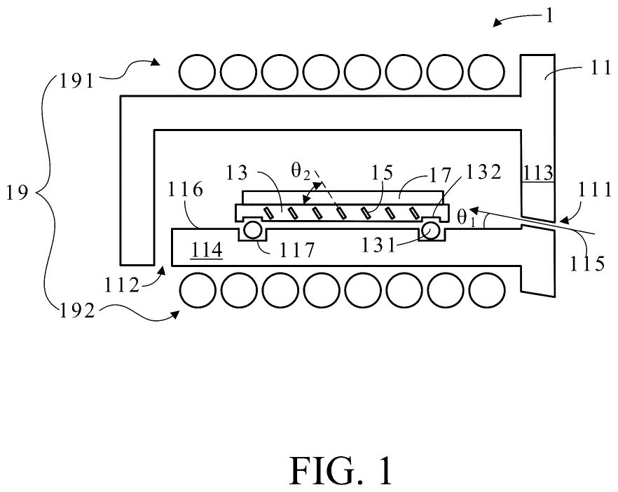

As shown in FIG. 1, the first embodiment of the present invention is thermal processing apparatus 1, which is applied to rapid thermal processing in semiconductor manufacturing. This embodiment is mainly applied to Rapid Thermal Processing (RTP); however, in other embodiments, it can also be applied to annealing processes, Rapid Thermal Oxidation (RTO) processes, or other processes requiring uniform temperature treatment of semiconductor substrates, thereby achieving a uniform temperature distribution during thermal processing.

The present invention discloses a thermal processing apparatus 1, comprising a processing chamber 11, a rotating susceptor 13, a plurality of airflow-driving elements 15, a support element 17, and a heat source 19.

The processing chamber 11 has an inlet 111 and an outlet 112. The inlet 111 and the outlet 112 are disposed on two opposing sides of the processing chamber 11. In the present embodiment, as shown in FIG. 1, the inlet 111 is arranged on a side wall 113 of the processing chamber 11, and the outlet 112 is arranged on a bottom 114 of the processing chamber 11. An inflow direction 115 of the inlet 111 forms an oblique angle θ₁ with an installation plane 116 of the processing chamber 11, and the oblique angle θ₁ is less than 90 degrees.

In this embodiment, the gas entering the processing chamber 11 is nitrogen. In other embodiments, it may be another gas that does not react with the semiconductor substrate. The gas enters the processing chamber 11 through the inlet 111 at the oblique angle θ₁ in an upward direction. The flow rate of the gas is 20 to 120 liters per minute (20-120 L/min), and the gas pressure of the gas is 1 atmosphere (atm).

As shown in FIG. 1, the rotating susceptor 13 is disposed within the processing chamber 11 and is made of quartz. A bearing 131 is provided at the bottom of the rotating susceptor 13, allowing the rotating susceptor 13 to rotate relative to the processing chamber 11. The detailed rotation mechanism will be described later.

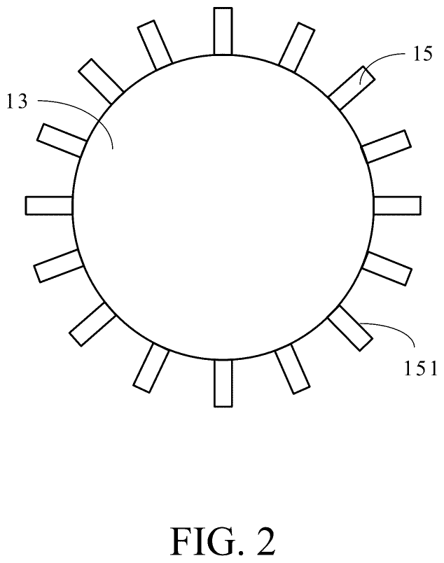

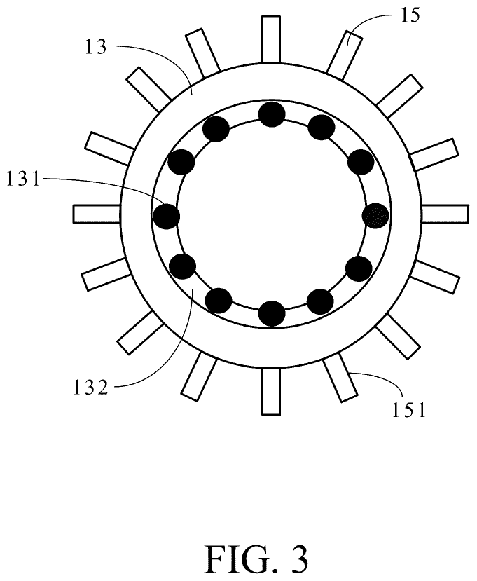

Referring to FIGS. 2 and 3, which are respectively a top view and a bottom view of the rotating susceptor 13 and the airflow-driving elements 15. In this embodiment, the airflow-driving elements 15 are spaced apart and arranged around an outer surface of the rotating susceptor 13. Each airflow-driving element 15 has the same spacing. The airflow-driving elements 15 comprise a plurality of blades. As illustrated, the number of airflow-driving elements 15 in this embodiment is 16 blades as an example, but in other embodiments of the present invention, the number may also be selected from 4 to 15.

Each of the airflow-driving elements 15 has a windward surface 151 configured to receive the gas entering the processing chamber 11. In this embodiment, the windward surface 151 has a length of 20 millimeters (mm), a width of 10 millimeters (mm), and a thickness of 1 millimeter (mm). As shown in FIG. 1, each airflow-driving element 15 forms an angle θ₂ of 15 to 90 degrees with an upper surface of the rotating susceptor 13.

The support element 17 is disposed on the rotating susceptor 13 and is configured to carry a substrate (not shown). In this embodiment, the support element 17 is made of graphite to provide good thermal conductivity and mechanical strength. In addition, an outer surface of the support element 17 has a silicon carbide (SiC) coating, thereby enhancing the high-temperature resistance, oxidation resistance, and chemical corrosion resistance of the support element 17.

The heat source 19 is arranged on a surface of the processing chamber 11 to provide radiant heat energy to the substrate on the support element 17. The heat source 19 comprises a plurality of upper heating elements 191 and a plurality of lower heating elements 192. In this embodiment, the upper heating elements 191 and the lower heating elements 192 are lamps, which are respectively disposed on an upper surface and a lower surface of the processing chamber 11, allowing the substrate to be heated uniformly from both top and bottom sides.

A bottom surface of the rotating susceptor 13 has a first annular groove 132, and the bearing 131 comprises a plurality of balls that are partially accommodated in the first annular groove 132. As shown in FIG. 1, the upper portion of each ball is partially accommodated in the first annular groove 132, allowing the balls to roll within the first annular groove 132 without disengaging from the rotating susceptor 13.

An inner bottom surface of the processing chamber 11 has a second annular groove 117, and the balls are partially accommodated in the second annular groove 117. As shown in FIG. 1, the lower portion of each ball is partially accommodated in the second annular groove 117, enabling the balls to roll within the second annular groove 117, providing rotation between the processing chamber 11 and the rotating susceptor 13 while maintaining their relative positions.

The bearing 131 is disposed on a lower surface of the rotating susceptor 13. In other embodiments of the present invention, the bearing may also be selected from other types of bearings, such as ball bearings, needle bearings, tapered roller bearings, sleeve bearings, magnetic bearings, air bearings, or fluid bearings. The connection between the rotating susceptor, the processing chamber, and the bearing may be adjusted according to the selected type of bearing.

When a gas enters the processing chamber 11 through the inlet 111, the oblique angle θ₁ of the inlet 111 directs the gas toward the windward surfaces 151 of the airflow-driving elements 15, thereby driving the airflow-driving elements 15 so that the rotating susceptor 13 rotates along with the support element 17. The gas is then discharged through the outlet 112.

In the present invention, the gas-driven rotation of the rotating susceptor and the support element within the processing chamber allows the substrate to be uniformly heated while rotating, thereby overcoming the problem in conventional thermal processing in which the heating lamps cannot provide a stable temperature across the entire substrate. Through the rotational movement of the substrate, the invention effectively reduces process variations caused by localized overheating or uneven heating, ensuring a uniform temperature distribution during the thermal processing. Moreover, the invention provides a low-cost, reliable, and contamination-free operating environment through a simple bearing structure, not only improving the overall temperature control accuracy of the substrate but also maintaining process stability and reliability, thereby enhancing the manufacturing yield and operational performance of semiconductor devices.

The above-described embodiments are essentially for illustrative purposes only and are not intended to limit the embodiments of the claimed subject matter or their applications or uses. Moreover, although at least one exemplary embodiment has been presented in the foregoing description, it should be understood that numerous modifications may still be made to the present invention. It should likewise be understood that the embodiments described herein are not intended to limit the scope, use, or configuration of the claimed subject matter in any way. On the contrary, the foregoing embodiments provide a convenient guide for those of ordinary skill in the art to implement one or more embodiments described herein. Furthermore, various modifications in function and arrangement of components may be made without departing from the scope defined by the appended claims, which encompass known equivalents as well as all foreseeable equivalents at the time of filing this patent application.

What is claimed is:

1. A thermal processing apparatus, comprising:
a processing chamber, having an inlet and an outlet;
a rotating susceptor, disposed within the processing chamber and including a bearing that allows the rotating susceptor to rotate relative to the processing chamber;
a plurality of airflow-driving elements, spaced apart and arranged around an outer surface of the rotating susceptor;
a support element, disposed on the rotating susceptor and configured to carry a substrate; and
a heat source, arranged on a surface of the processing chamber to provide radiant heat energy to the substrate on the support element;
wherein, when a gas enters the processing chamber through the inlet, the gas drives the airflow-driving elements to cause the rotating susceptor to rotate along with the support element, and is subsequently discharged through the outlet.

2. The thermal processing apparatus according to claim 1, wherein a bottom surface of the rotating susceptor has a first annular groove, and the bearing comprises a plurality of balls that are partially accommodated in the first annular groove.

3. The thermal processing apparatus according to claim 2, wherein an inner bottom surface of the processing chamber has a second annular groove, and the balls are partially accommodated in the second annular groove.

4. The thermal processing apparatus according to claim 1, wherein the airflow-driving elements comprise a plurality of blades.

5. The thermal processing apparatus according to claim 1, wherein the number of the airflow-driving elements is from 4 to 16.

6. The thermal processing apparatus according to claim 1, wherein each of the airflow-driving elements has a windward surface, a length of the windward surface is 20 millimeters (mm), and a width of the windward surface is 10 millimeters (mm).

7. The thermal processing apparatus according to claim 1, wherein each of the airflow-driving elements forms an angle of 15 to 90 degrees with an upper surface of the rotating susceptor.

8. The thermal processing apparatus according to claim 1, wherein the bearing is disposed on a lower surface of the rotating susceptor and is selected from a ball bearing, a needle bearing, a tapered roller bearing, a sleeve bearing, a magnetic bearing, an air bearing, or a fluid bearing.

9. The thermal processing apparatus according to claim 1, wherein the support element is made of graphite.

10. The thermal processing apparatus according to claim 6, wherein an outer surface of the support element has a silicon carbide (SiC) coating.

11. The thermal processing apparatus according to claim 1, wherein the rotating susceptor is made of quartz.

12. The thermal processing apparatus according to claim 1, wherein the inlet and the outlet are disposed on two opposing sides of the processing chamber, and the inlet is arranged on a side wall of the processing chamber.

13. The thermal processing apparatus according to claim 1, wherein an inflow direction of the inlet forms an oblique angle with an installation plane of the processing chamber, and the oblique angle is less than 90 degrees.

14. The thermal processing apparatus according to claim 1, wherein a flow rate of the gas is 20 to 120 liters per minute.

15. The thermal processing apparatus according to claim 1, wherein the gas is nitrogen.

16. The thermal processing apparatus according to claim 1, wherein a gas pressure of the gas is 1 atmosphere (atm).

17. The thermal processing apparatus according to claim 1, wherein the heat source comprises a plurality of upper heating elements and a plurality of lower heating elements, which are respectively disposed on an upper surface and a lower surface of the processing chamber.
